(19) United States
(12) Patent Application Publication
(10) Pub. No.: US 2007/0275330 A1
(43) Pub. Date: Nov. 29, 2007

(54) BOTTOM ANTI-REFLECTIVE COATING

(75) Inventors: Todd C. Bailey, Poughkeepsie, NY (US); Wai-Kin Li, Beacon, NY (US); Sajan Marokkey, Wappingers Falls, NY (US); Dirk Pfeiffer, Dobbs Ferry, NY (US)

Correspondence Address: FREDERICK W. GIBB, III;Gibb & Rahman, LLC, 2568-A RIVA ROAD, SUITE 304, ANNAPOLIS, MD, 21401, US

(73) Assignees: INTERNATIONAL BUSINESS MACHINES CORPORATION, ARMONK, NY (US); INFINEON TECHNOLOGIES NORTH AMERICA CORP., SAN JOSE, CA (US)

(21) Appl. No.: 11/420,251

(22) Filed: May 25, 2006

(51) Int. Cl. G03F 7/26

(52) U.S. Cl. 430/311; 430/270.1; 430/950

(57) ABSTRACT

Disclosed are embodiments of a bi-layer bottom anti-reflective coating (BARC) with graded optical properties (i.e., a graded refractive index) and a method of forming the BARC. The BARC is formed by sequentially coating two BARC layers onto a substrate. Each BARC layer comprises a polymer and an optical component, each has slightly different optical properties, and each is processed such that either the polymers partially intermix or the optical component partially diffuses between the layers in order to create a graded chromophore concentration across the resulting BARC. Thus, a gradual transition of optical properties is created from the substrate/BARC interface to the BARC/photo-resist interface.

### BACKGROUND

1. Field of the Invention

The embodiments of the invention generally relate to anti-reflective coatings, and, more particularly, to a bi-layer anti-reflective coating.

2. Description of the Related Art

Reflectivity control is a known challenge with lithography technologies employing chemical lasers capable of generating short wavelengths (i.e., excimer lasers such as, 193 nm argon-flouride (ArF) excimer lasers). Typical control of substrate reflectivity involves bottom anti-reflective coatings (BARCs). These BARCs rely on a combination of thin film interference and absorption for reflection suppression in order to suppress substrate reflections to improve resist profile, depth of focus, exposure latitude and critical dimension (CD) control. There are typically different optimal BARC thicknesses for each underlying film stack. However, at lower wavelengths (e.g., 193 nm wavelength (ArF) as opposed to 248 nm wavelength (krypton-flouride (KrF)) and higher numerical aperture (>1.0 NA) single-layer BARC films do not provide sufficient reflectivity control.

One technique that allows for increased reflectivity control is to use multiple, thin BARCs (e.g., dual- or multi-layer BARC schemes) designed to match the complex refractive indices at the top interface between the photo-resist and the BARC and the bottom interface between the substrate and the BARC. Specifically, it has been theorized that only graded BARCs can fully suppress reflectivity swing. For example, see the following prior art documents incorporated herein by reference: U.S. Pat. Appl. Pub. No. 20030211755, Lu, et al. of Nov. 13, 2003; U.S. Pat. No. 6,316,167 of Angelopouos et al., Nov. 13, 2001; U.S. Pat. No. 6,479,401 of Linliu et al., Nov. 12, 2002; U.S. Pat. No. 6,428,894 of Babich et al., Aug. 6, 2002; and A. P. Mahorowala et al., Porc. SPIE v. 4343 (2001) p. 306). Ideal grading requires complete matching of the complex refractive indices at the top interface between the photo-resist and the BARC and the bottom interface between the substrate and the BARC so that CD is reasonably independent from overall BARC thickness. However, prior art methods of forming graded BARCs often result in less than ideal grading and, thus, do not eliminate CD dependency on BARC thickness. Additionally, these prior art methods often increase process complexity with each added layer. Therefore, there is a need in the art for a BARC structure with optimal grading and a method of forming the structure that offers minimal process complexity.

### SUMMARY

In view of the foregoing, disclosed herein are embodiments that include a bi-layer bottom anti-reflective coating (BARC) with graded optical properties (i.e., a graded refractive index) and a method of forming the BARC. Specifically, the BARC of the invention is formed by sequentially coating two BARC layers onto a substrate. Each BARC layer comprises a polymer and an optical component, each has slightly different optical properties, and each is processed such that either the layers partially intermix or the optical component partially diffuses between the layers in order to create a graded chromophore concentration across the BARC. Thus, a gradual transition of material properties is created from the substrate/BARC interface to the BARC/photo-resist interface.

More specifically, an embodiment of the invention comprises a bottom anti-reflective coating (BARC) to be used in conjunction with a photo-resist above a substrate in order to gain process latitude on critical process layers (i.e., to suppress substrate reflections to improve critical dimension control). The BARC is a bi-layer BARC with first and second layers that comprise either the same or different polymers (i.e., a first polymer and a second polymer, respectively). For example, either layer of the BARC can comprise an acrylate-based polymer or a styrene-based polymer. However, due to heating techniques used in the formation process both the first and second polymers should have a glass transition temperature that is lower than the cross-linking temperature (e.g., between approximately 80 and 100° C.).

Additionally, the BARC comprises a chromophore component in both the first layer and the second layer. The concentration of this chromophore component is graded between the bottom surface of the first layer adjacent to the substrate and the top surface of the second layer. The concentration of the chromophore component at the bottom surface can be predetermined so that the refractive index of the first layer at the bottom surface (i.e., the first refractive index) is approximately the same as the refractive index of the substrate (i.e., the second refractive index). For example, the concentration of the chromophore at the bottom surface can be between approximately 30 and 50 mole percent in order to possess optical properties similar to those of the underlying substrate (e.g., absorbing at 193 nm exposure). Whereas, the concentration of the chromophore component at the top surface is predetermined so that the refractive index of the second layer at the top surface (i.e., the third refractive index) is approximately the same as the refractive index of a selected photo-resist material (i.e., a fourth refractive index). For example, the concentration of the chromophore at the top surface can be between approximately 0 and 20 mole percent in order to posses optical properties similar to those of the selected photo-resist (e.g., transparent at 193 nm). Between the bottom surface with the higher chromophore concentration and the top surface with the lower or zero chromophore concentration, the concentration of the chromophore gradually decreases (i.e., transitions or is graded). Thus, the BARC exhibits optical properties that transition between the bottom surface and the top surface from absorbing light at a first wavelength to transmitting light at the first wavelength.

Also, disclosed herein are embodiments of a method of forming the anti-reflective coating, described above.

One embodiment involves the diffusion of a chromophore component from a first layer to a second layer in order to create a graded chromophore concentration between the bottom and top surfaces of the resulting BARC so that the refractive index of the BARC at its bottom surface approximately matches that of the substrate and the refractive index of the BARC at its top surface approximately matches that of a selected photo-resist material. Specifically, this embodiment comprises forming a first layer on a substrate and a second layer on the first layer.

This first layer is formed with a first polymer component, a chromophore component and a solvent component and can, for example, be deposited on the substrate using a “spin-on” technique. The first polymer can, for example, be selected from a group of organic polymers including an acrylate-based polymer or a styrene-based polymer. Additionally, this first polymer should be selected from a group of polymers that have a glass transition temperatures that is between approximately 80 and 100° C.

The first layer is specifically formed to have a refractive index (i.e., a first refractive index) that is approximately equal to the refractive index (i.e., the second refractive index) of the substrate. Thus, the first layer is formed to have approximately the same optical properties as the substrate. To accomplish this, a chromophore component is selected that absorbs light at first wavelength (e.g., absorbs light at 193 nm exposure). Then, the chromophore component is combined with the first polymer component such that the chromophore component comprises approximately 30-50 mole percent of the first layer. The chromophore component can be combined with the first polymer component by either chemically attaching the chromophore component to a backbone of the first polymer component or simply blending the chromophore component with the first polymer component.

After the first layer is deposited, the first layer can be heated (e.g., baked at a temperature between a conventional soft bake and a conventional hard bake, such as, between approximately 100 and 150° C.) to remove the solvent component and to partially, but not totally, cross-link the first polymer component. Note that partial cross-linking facilitates partial, but not complete, diffusion of the chromophore component from the first layer to the subsequently formed second layer during subsequent processing in order to achieve the desired graded chromophore concentration (i.e., this baking process allows, but limits chromophore diffusion, during a subsequent hard bake).

The second layer is formed with a second polymer component and a solvent component. As with the first layer, the second layer can be deposited using a “spin-on” technique, can be selected from a group of polymers including an acrylate-based polymer or a styrene-based polymer, and should be selected from a group of polymers that have a glass transition temperatures that is between approximately 80 and 100° C. This second layer is specifically formed to have a refractive index (i.e., a third refractive index) that is approximately equal to the refractive index (i.e., the fourth refractive index) of a selected photo-resist material. Thus, the second layer is formed to have approximately the same optical properties as the selected photo-resist layer (e.g., the second layer is formed so that it is transmits light or is transparent to light at the first wavelength). To accomplish this, the second layer can be formed with or without a chromophore component. If the second layer is formed with a chromophore component, it may be the same or different from the chromophore component in the first layer. However, the concentration of the chromophore component in the second layer should not be greater than approximately 20 mole percent of the second layer.

After the second layer is formed both the first and second layers are heated (e.g., using a hard bake process with a temperature, for example, between 150 and 200° C.). This hard bake process is used to diffuse a portion of the chromophore component from an upper section of the first layer into a lower section of the second layer in order to create a graded chromophore concentration between the bottom surface of the resulting anti-reflective coating and the top surface of the resulting anti-reflective coating. This graded chromophore concentration allows the anti-reflective coating to exhibit optical properties that transition between absorbing light at the first wavelength at the bottom surface and transmitting light (e.g., transparent to light) at the first wavelength at the top surface. The hard bake process also functions to fully cross-link the polymers in the first and second layers.

Another embodiment involves the partial intermixing of two layers in order to create a graded chromophore concentration between the bottom and top surfaces of the resulting BARC so that the refractive index of the BARC at its bottom surface approximately matches that of the substrate and the refractive index of the BARC at its top surface approximately matches that of a selected photo-resist material. Specifically, this embodiment comprises forming a first layer on a substrate and a second layer on the first layer.

The first layer is formed with a first polymer component, a chromophore component and a solvent component and can, for example, be deposited on the substrate using a “spin-on” technique. The first polymer can, for example, be selected from a group of organic polymers including an acrylate-based polymer or a styrene-based polymer. Additionally, this first polymer should be selecting from a group of polymers that have a glass transition temperatures that is between approximately 80 and 100° C.

The first layer is specifically formed to have a refractive index (i.e., a first refractive index) that is approximately equal to the refractive index (i.e., the second refractive index) of the substrate. Thus, the first layer is formed to have approximately the same optical properties as the substrate. To accomplish this, a chromophore component is selected that absorbs light at first wavelength (e.g., absorbs light at 193 nm exposure). Then, the chromophore component is combined with the first polymer component such that the chromophore component comprises approximately 30-50 mole percent of the first layer. The chromophore component can be combined with the first polymer component by either chemically attaching the chromophore component to a backbone of the first polymer component or simply blending the chromophore component with the first polymer component.

After the first layer is deposited, the first layer can be heated (e.g., using a soft bake process with a temperature of less than approximately 100° C.) to remove the solvent component and to partially, but not totally, cross-link the first polymer component. Note that partial cross-linking facilitates partial, but not complete, intermixing of the first layer with the second layer during subsequent processing in order to achieve the desired graded chromophore concentration (i.e., this baking process allows, but limits, intermixing during a subsequent hard bake).

The second layer is formed with a second polymer component and a solvent component. As with the first layer, the second layer can be deposited using a “spin-on” technique, can be selected from a group of polymers including an acrylate-based polymer or a styrene-based polymer, and should be selected from a group of polymers that have a glass transition temperatures that is between approximately 80 and 100° C. This second layer is specifically formed to have a refractive index (i.e., a third refractive index) that is approximately equal to the refractive index (i.e., the fourth refractive index) of a selected photo-resist material. Thus, the second layer is formed to have approximately the same optical properties as the selected photo-resist layer (e.g., the second layer is formed so that it is transmits light or is transparent to light at the first wavelength). To accomplish this, the second layer can be formed with or without a chromophore component. If the second layer is formed with a chromophore component, it may be the same or different from the chromophore component in the first layer. However, the concentration of the chromophore component in the second layer should not be greater than approximately 20 mole percent of the second layer.

After the second layer is formed both the first and second layers are heated (e.g., using a hard bake process with temperatures, for example, between 150 and 200° C.). This hard bake process is used to intermix an upper section of the first layer with a lower section of the second layer in order to create a graded chromophore concentration between the bottom surface of the resulting anti-reflective coating and the top surface of the resulting anti-reflective coating. Specifically, the soft bake of the first layer allows moderate swelling to occur during the coating of the second material, which enhances intermixing of the polymer matrices between the two materials. However, due to the partial cross-linking intermixing is not complete. This graded chromophore concentration allows the anti-reflective coating to exhibit optical properties that transition between absorbing light at the first wavelength at the bottom surface and transmitting light at the first wavelength at the to surface. The hard bake process also functions to fully cross-link the polymers in the first and second layers.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic diagram illustrating an embodiment of the anti-reflective coating of the invention;

FIG. 2 is a flow diagram illustrating an embodiment of the method of forming the anti-reflective coating of the invention;

FIG. 3 is a schematic diagram illustrating a partially-completed structure formed according to the method of FIG. 2;

FIG. 4 is a schematic diagram illustrating a partially-completed structure formed according to the method of FIG. 2

FIG. 5 is a schematic diagram illustrating a partially-completed structure formed according to the method of FIG. 2

FIG. 6 is a schematic diagram illustrating a completed structure formed according to the method of FIG. 2;

FIG. 7 is a flow diagram illustrating an embodiment of the method of forming the anti-reflective coating of the invention;

FIG. 8 is a schematic diagram illustrating a partially-completed structure formed according to the method of FIG. 7;

FIG. 9 is a schematic diagram illustrating a partially-completed structure formed according to the method of FIG. 7;

FIG. 10 is a schematic diagram illustrating a partially-completed structure formed according to the method of FIG. 7; and

FIG. 11 is a schematic diagram illustrating a completed structure formed according to the method of FIG. 7.

### DETAILED DESCRIPTION OF PREFERRED EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, one technique that allows for increased critical dimension (CD) swing control is to use multiple, thin BARCs (e.g., dual- or multi-layer BARC schemes) designed to match the complex refractive indices at the top interface between the photo-resist and the BARC and the bottom interface between the substrate and the BARC. It has been theorized that only graded BARCs can fully suppress reflectivity swing. However, ideal grading requires complete matching of the complex refractive indices at the top interface between the photo-resist and the BARC and the bottom interface between the substrate and the BARC so that CD is reasonably independent from overall BARC thickness and prior art methods of forming graded BARCs often result in less than ideal grading. Thus, such methods do not eliminate CD dependency on BARC thickness. Additionally, these prior art methods often increase process complexity with each added layer. Therefore, there is a need in the art for a BARC structure with optimal grading and a method of forming the structure that offers minimal process complexity.

In view of the foregoing, disclosed herein are embodiments of a bi-layer bottom anti-reflective coating (BARC) with graded optical properties (i.e., a graded refractive index) and a method of forming the BARC. Specifically, the BARC of the invention is formed by sequentially coating two BARC layers onto a substrate. Each BARC layer comprises a polymer and an optical component, each has slightly different optical properties, and each is processed such that either the layers partially intermix or the optical component partially diffuses between the layers in order to create a graded chromophore concentration across the resulting BARC. Thus, a gradual transition of optical properties is created from the substrate/BARC interface to the BARC/photo-resist interface.

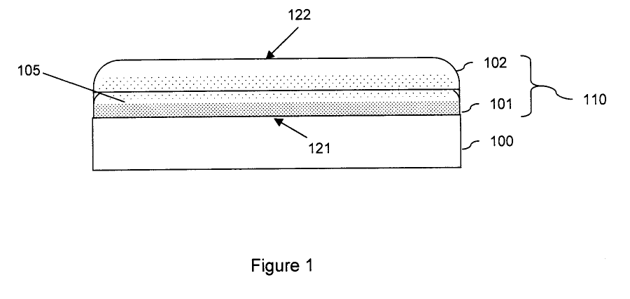

More specifically, referring to FIG. 1, an embodiment of the invention comprises a bottom anti-reflective coating (BARC) 110 to be used in conjunction with a photo-resist above a substrate 100 in order to gain process latitude on critical process layers (i.e., to suppress substrate reflections to improve critical dimension control). The BARC 110 is a bi-layer BARC with first and second layers 101, 102 that comprise either the same or different polymers (i.e., a first polymer and a second polymer, respectively). For example, either layer 101, 102 of the BARC 110 can comprise an acrylate-based polymer or a styrene-based polymer. However, due to heating techniques used in the formation process both the first and second polymers should have a glass transition temperature that is lower than the cross-linking temperature (e.g., between approximately 80 and 100° C.).

Additionally, the BARC 110 comprises a chromophore component 105 in both the first layer 101 and the second layer 102. The concentration of this chromophore component 105 is graded between the bottom surface 121 of the first layer 101 adjacent to the substrate 100 and the top surface 122 of the second layer 102. The concentration of the chromophore component 105 at the bottom surface 121 can be predetermined so that the refractive index of the first layer 101 at the bottom surface 121 (i.e., the first refractive index) is approximately the same as the refractive index of the substrate 100 (i.e., the second refractive index). For example, the concentration of the chromophore 105 at the bottom surface 121 can be between approximately 30 and 50 mole percent in order to possess optical properties similar to those of the underlying substrate 100 (e.g., absorbing at 193 nm exposure). Whereas, the concentration of the chromophore component 105 at the top surface 122 is predetermined so that the refractive index of the second layer 102 at the top surface 122 (i.e., the third refractive index) is approximately the same as the refractive index of a selected photo-resist material (i.e., a fourth refractive index) that will be deposited during subsequent lithography processing. For example, the concentration of the chromophore 105 at the top surface 122 can be between approximately 0 and 20 mole percent in order to posses optical properties similar to those of the selected photo-resist (e.g., transparent at 193 nm). Between the bottom surface 121 with the higher chromophore concentration and the top surface 122 with the lower or zero chromophore concentration, the concentration of the chromophore 105 gradually decreases (i.e., transitions or is graded). Thus, the BARC 110 exhibits optical properties that transition between the bottom surface 121 and the top surface 122 from absorbing light at a first wavelength to transmitting light at that first wavelength.

Also, disclosed herein are embodiments of a method of forming the anti-reflective coating, described above.

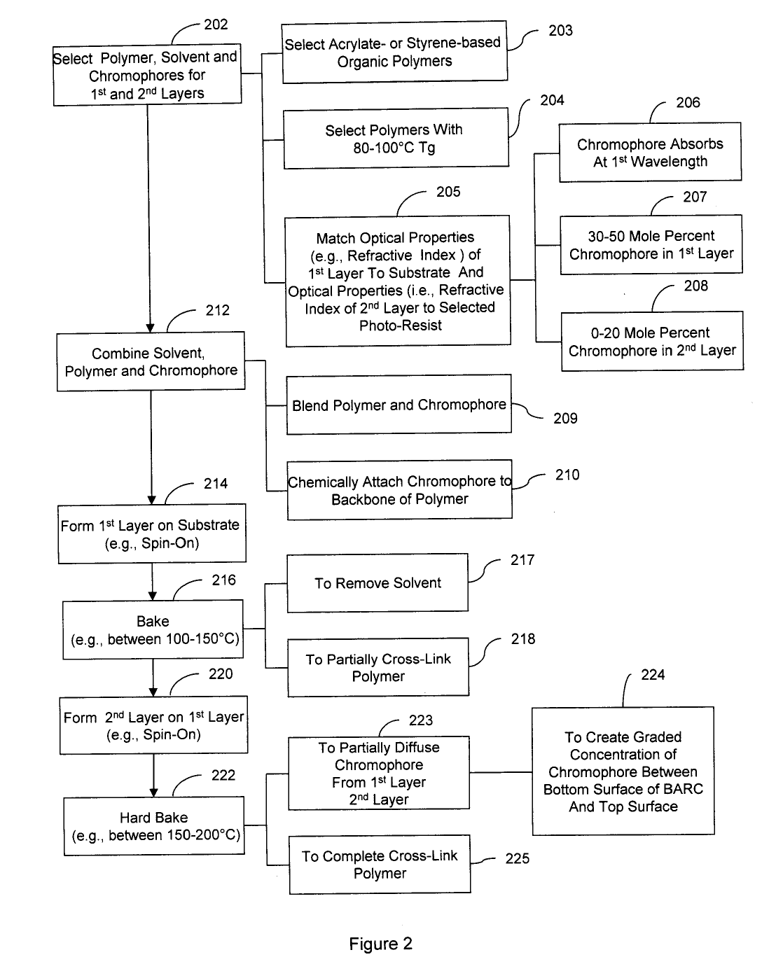

Referring to FIG. 2, one embodiment of the method of the invention involves the formation of the BARC by sequentially coating two BARC layers onto a substrate. Each BARC layer comprises a polymer and an optical component, each has slightly different optical properties, and each is processed such that the optical component partially diffuses from one layer into the other in order to create a graded chromophore concentration across the resulting BARC. Thus, a gradual transition of optical properties is created from the substrate/BARC interface to the BARC/photo-resist interface. Specifically, this embodiment involves the diffusion of a chromophore component from a first layer to a second layer in order to create a graded chromophore concentration between the bottom and top surfaces of the resulting BARC so that the refractive index of the BARC at its bottom surface approximately matches that of the substrate and the refractive index of the BARC at its top surface approximately matches that of a selected photo-resist material.

The first layer of the BARC is formed by first selecting a first polymer component, a chromophore component and a solvent component (202). The first polymer can, for example, be selected from a group of organic polymers including an acrylate-based polymer or a styrene-based polymer (203). Additionally, this first polymer should be selected from a group of polymers that have a glass transition temperatures (Tg) that is below the crosslinking temperature (e.g., between approximately 80 and 100° C.) (204). Controlling the Tg is generally possible by choosing the appropriate molecular weight during the polymerization which is well known to those in the art.

The first layer is specifically formed to have a refractive index (i.e., a first refractive index) that is approximately equal to the refractive index (i.e., the second refractive index) of the substrate (205). Thus, the first layer is formed to have approximately the same optical properties as the substrate. To accomplish this, a chromophore component is selected that absorbs light at first wavelength (e.g., absorbs light at 193 nm exposure) (206). Then, the chromophore component is combined with the first polymer component such that the chromophore component comprises approximately 30-50 mole percent of the first layer (207). The chromophore component can be combined with the first polymer component and the solvent component (at process 212) by either chemically attaching the chromophore component to a backbone of the first polymer component (210) or simply blending the chromophore component with the first polymer component (209).

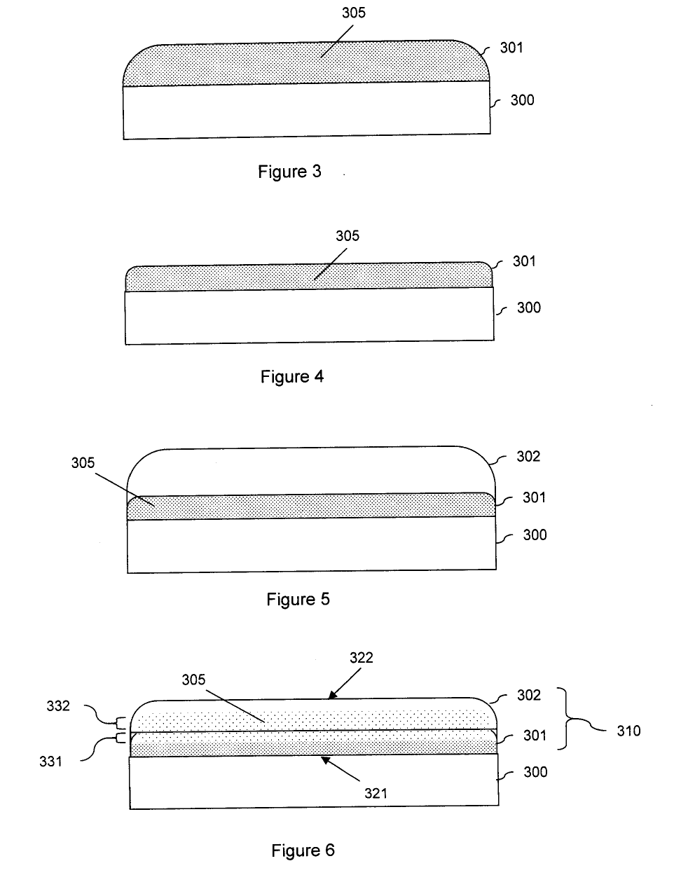

Once the various components (polymer, solvent and chromophore 305) of the first layer 301 are combined (at process 212), the first layer 301 can, for example, be deposited on the substrate 300 using a “spin-on” technique (214; see FIG. 3). After the first layer 301 is deposited (at process 214), the first layer 301 can be heated (216, see FIG. 4) (e.g., baked at a temperature between a conventional soft bake and a conventional hard bake, such as, between approximately 100 and 150° C.) to remove the solvent component (217) and to partially, but not totally, cross-link the first polymer component (218). Note that partial cross-linking facilitates partial, but not complete, diffusion of the chromophore component 305 from the first layer 301 to the subsequently formed second layer (see layer 302 of FIGS. 5-6) during subsequent processing (at process 220-225 discussed below) in order to achieve the desired graded chromophore concentration (i.e., this baking process allows, but limits, chromophore 305 diffusion, during a subsequent hard bake (at process 222)).

The second layer 302 is similarly formed by first selecting a second polymer component, a chromophore component and a solvent component (202). As with the first polymer of the first layer, the second polymer of the second layer can be selected from a group of polymers including an acrylate-based polymer or a styrene-based polymer (203) and should be selected from a group of polymers that have a glass transition temperatures that is below the cross-linking temperature (e.g., between approximately 80 and 100° C.) (204). Again, controlling the Tg is generally possible by choosing the appropriate molecular weight during the polymerization which is well known to those in the art.

This second layer is specifically formed to have a refractive index (i.e., a third refractive index) that is approximately equal to the refractive index (i.e., the fourth refractive index) of a selected photo-resist material (205). Thus, the second layer is formed to have approximately the same optical properties as the selected photo-resist layer (e.g., the second layer is formed so that it is transmits light or is transparent to light at the first wavelength). To accomplish this, the second layer can be formed with or without a chromophore component (208). If the second layer is formed with a chromophore component, it may be the same or different from the chromophore component in the first layer. However, the concentration of the chromophore component in the second layer should not be greater than approximately 20 mole percent of the second layer.

If a chromophore component is incorporated into the second layer, it can be combined with the second polymer component and the solvent component (at process 212) by either chemically attaching the chromophore component to a backbone of the first polymer component (210) or simply blending the chromophore component with the first polymer component (209).

Once the various components (polymer, solvent and optional chromophore 305) of the second layer 302 are combined (at process 212), the second layer 302 can, for example, be deposited onto the first layer 301 using a “spin-on” technique (220; see FIG. 5). After the second layer is formed both the first and second layers 301-302 are heated (222) (e.g., using a hard bake process with a temperature, for example, between 150 and 200° C.). This hard bake process (222) is used to diffuse a portion of the chromophore component 305 from an upper section 331 of the first layer 301 into a lower section 332 of the second layer 302 (223, see FIG. 6) in order to create a graded chromophore 305 concentration between the bottom surface 321 of the resulting anti-reflective coating 310 and the top surface 322 of the resulting anti-reflective coating 310 (224). The degree of diffusion may be controlled by the crosslinking density of the film which will be affected by the amount of crosslinker, acid generator and bake temperature. This graded chromophore 305 concentration allows the anti-reflective coating 310 to exhibit optical properties that transition between absorbing light at the first wavelength at the bottom surface 321 and transmitting light (e.g., transparent to light) at the first wavelength at the top surface 322. The hard bake process (222) also functions to fully cross-link the polymers in the first 301 and second 302 layers (225).

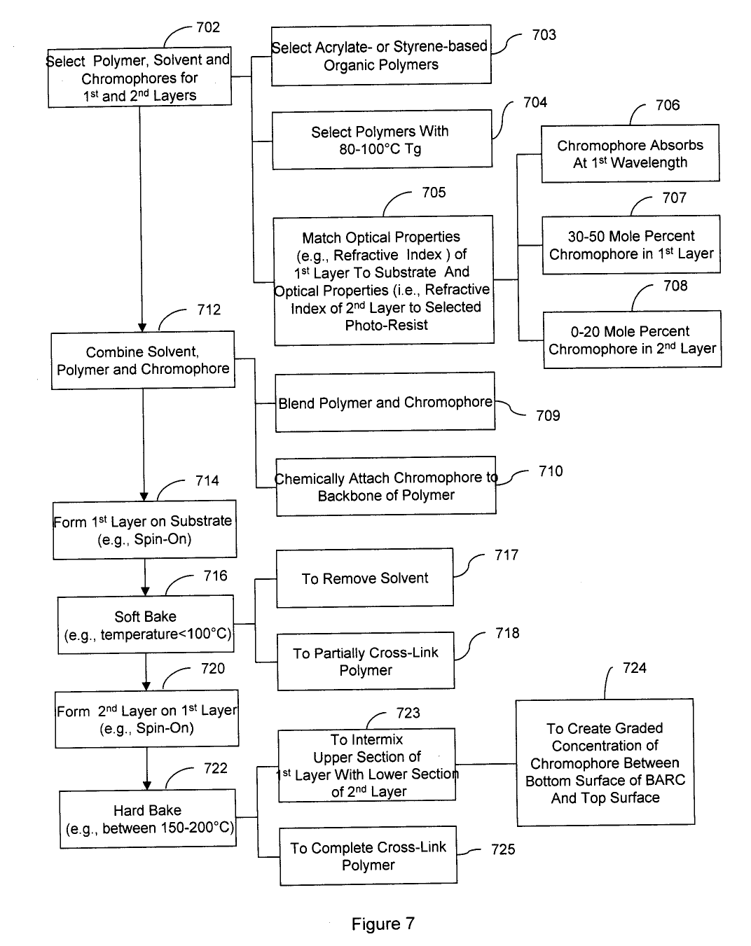

Referring to FIG. 7, another embodiment of the method of the invention also involves the formation of the BARC by sequentially coating two BARC layers onto a substrate. Each BARC layer comprises a polymer and an optical component, each has slightly different optical properties, and each is processed such that the layers partially intermix in order to create a graded chromophore concentration across the resulting BARC. Thus, a gradual transition of optical properties is created from the substrate/BARC interface to the BARC/photo-resist interface. Specifically, this embodiment involves the intermixing of polymer matrices between an upper portion of a first layer and a lower portion of a second layer in order to create a graded chromophore concentration between the bottom and top surfaces of the resulting BARC so that the refractive index of the BARC at its bottom surface approximately matches that of the substrate and the refractive index of the BARC at its top surface approximately matches that of a selected photo-resist material.

The first layer of the BARC is formed by first selecting a first polymer component, a chromophore component and a first solvent component (702). The first polymer can, for example, be selected from a group of organic polymers including an acrylate-based polymer or a styrene-based polymer (703). Additionally, this first polymer should be selecting from a group of polymers that have a glass transition temperature that is below the cross-linking temperature (e.g., between approximately 80 and 100° C.) (704). Controlling the Tg is generally possible by choosing the appropriate molecular weight during the polymerization which is well known to those in the art.

The first layer is specifically formed to have a refractive index (i.e., a first refractive index) that is approximately equal to the refractive index (i.e., the second refractive index) of the substrate (705). Thus, the first layer is formed to have approximately the same optical properties as the substrate. To accomplish this, a chromophore component is selected that absorbs light at first wavelength (e.g., absorbs light at 193 nm exposure) (706). Then, the chromophore component is combined with the first polymer component such that the chromophore component comprises approximately 30-50 mole percent of the first layer (707). The chromophore component can be combined with the first polymer component and the solvent component (at process 712) by either chemically attaching the chromophore component to a backbone of the first polymer component (710) or simply blending the chromophore component with the first polymer component (709).

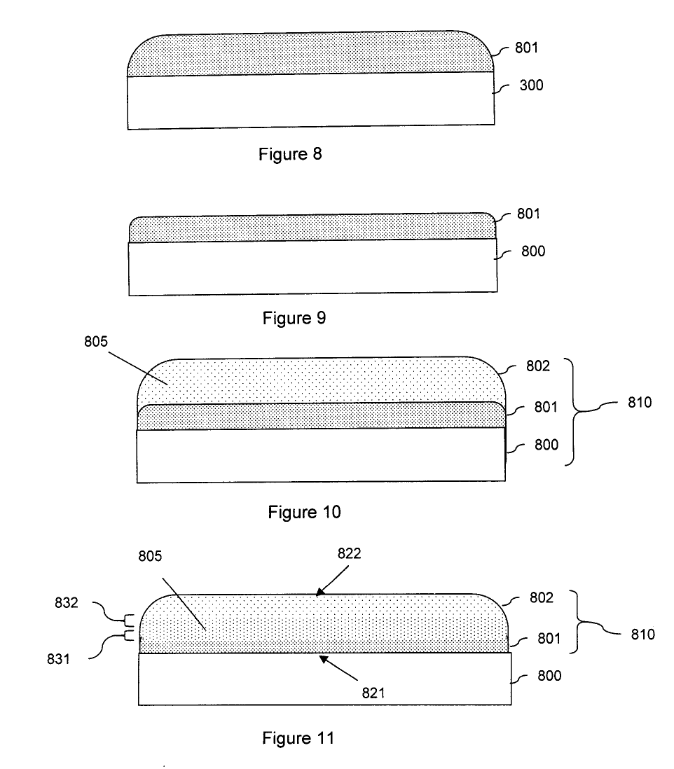

Once the various components (polymer, solvent and chromophore 805) of the first layer 801 are combined (at process 712), the first layer 801 can, for example, be deposited on the substrate 800 using a “spin-on” technique (714; see FIG. 8). After the first layer 801 is deposited (at process 714), the first layer 801 can be heated (716, see FIG. 9) (e.g., using a soft bake process with a temperature of less than approximately 100° C.) to remove the solvent component (717) and to partially, but not totally, cross-link the first polymer component (718). Note that partial cross-linking facilitates partial, but not complete, intermixing of the first layer 301 with the second layer (see second layer 302 of FIGS. 10-11) during subsequent processing (at processes 720-725) in order to achieve the desired graded chromophore 805 concentration (i.e., this baking process allows, but limits intermixing of the layers 801 and 802, during a subsequent hard bake at process 722).

The second layer 802 is similarly formed by first selecting a second polymer component, a chromophore component and a second solvent component (702). As with the first polymer of the first layer, the second polymer of the second layer can be selected from a group of polymers including an acrylate-based polymer or a styrene-based polymer (703) and should be selected from a group of polymers that have a glass transition temperatures that below the cross-linking temperature (e.g., between approximately 80 and 100° C.) (704). Again, controlling the Tg is generally possible by choosing the appropriate molecular weight during the polymerization which is well known to those in the art.

This second layer is specifically formed to have a refractive index (i.e., a third refractive index) that is approximately equal to the refractive index (i.e., the fourth refractive index) of a selected photo-resist material (705). Thus, the second layer is formed to have approximately the same optical properties as the selected photo-resist layer (e.g., the second layer is formed so that it is transmits light or is transparent to light at the first wavelength). To accomplish this, the second layer can be formed with or without a chromophore component (708). If the second layer is formed with a chromophore component, it may be the same or different from the chromophore component in the first layer. However, the concentration of the chromophore component in the second layer should not be greater than approximately 20 mole percent of the second layer.

If a chromophore component is incorporated into the second layer, it can be combined with the second polymer component and the second solvent component (at process 712) by either chemically attaching the chromophore component to a backbone of the first polymer component (710) or simply blending the chromophore component with the first polymer component (709).

Once the various components (polymer, solvent and optional chromophore 805) of the second layer 802 are combined (at process 712), the second layer 802 can, for example, be deposited onto the first layer 801 using a “spin-on” technique (720; see FIG. 10). Depositing the second layer onto the first layer, causes the first layer to come into contact with the second solvent component and, thereby swell. After the second layer 802 is formed both the first 801 and second 802 layers are heated (722) (e.g., using a hard bake process with temperatures, for example, between 150 and 200° C.). This hard bake process (722) is used to intermix an upper section 831 of the first layer 801 with a lower section 832 of the second layer 802 (723, see FIG. 11) in order to create a graded chromophore 805 concentration between the bottom surface 821 of the resulting anti-reflective coating 810 and the top surface 822 of the resulting anti-reflective coating 810 (724). The moderate swelling, which occurs in the first layer when the first layer comes into contact with the solvent of the second layer, enhances intermixing of the polymer matrices between the two materials 801, 802. However, due to the partial cross-linking intermixing is not complete. The degree of intermixing may be controlled by the crosslinking density of the film which will be affected by the amount of crosslinker, acid generator and bake temperature. This graded chromophore 805 concentration allows the anti-reflective coating 810 to exhibit optical properties that transition between absorbing light at the first wavelength at the bottom surface and transmitting light at the first wavelength at the to surface. The hard bake process (722) also functions to fully cross-link the polymers in the first and second layers 801, 802 (725).

Therefore, disclosed are embodiments of a bi-layer bottom anti-reflective coating (BARC) with graded optical properties (i.e., a graded refractive index) and a method of forming the BARC. The BARC is formed by sequentially coating two BARC layers onto a substrate. Each BARC layer comprises a polymer and an optical component, each has slightly different optical properties, and each is processed such that either the layers partially intermix or the optical component partially diffuses between the layers in order to create a graded chromophore concentration across the resulting BARC. Thus, a gradual transition of optical properties is created from the substrate/BARC interface to the BARC/photo-resist interface.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. An anti-reflective coating comprising:
a first layer having a bottom surface adjacent to a substrate, wherein said first layer comprises a first polymer;
a second layer on said first layer and having a top surface, wherein said second layer comprises a second polymer; and
a chromophore component in said first layer and said second layer, wherein said chromophore component is selected to absorb light at a first wavelength and a concentration of said chromophore component is graded between said bottom surface and said top surface such that said anti-reflective coating exhibits optical properties that transition between said bottom surface and said top surface from absorbing light at a first wavelength to transmitting light at said first wavelength.

2. The coating of claim 1, wherein said concentration of said chromophore component at said bottom surface is approximately 30-50 mole percent.

3. The coating of claim 1, wherein said concentration of said chromophore component at said bottom surface is predetermined so that a first refractive index of said first layer at said bottom surface approximately matches a second refractive index of said substrate.

4. The coating of claim 1, wherein said concentration of said chromophore component at said top surface is approximately 0-20 mole percent.

5. The coating of claim 1, wherein said concentration of said chromophore component at said top surface is predetermined such that a third refractive index of said second layer at said top surface approximately matches a fourth refractive index of a selected photo-resist material positioned above said second layer.

6. The coating of claim 1, wherein said first polymer comprises one of an acrylate-based polymer and a styrene-based polymer and wherein said second polymer comprises one of an acrylate-based polymer and a styrene-based polymer.

7. An anti-reflective coating comprising:
a first layer having a bottom surface adjacent to a substrate, wherein said first layer comprises a first polymer;
a second layer on said first layer and having a top surface, wherein said second layer comprises a second polymer; and
a chromophore component in said first layer and said second layer,
wherein said chromophore component is selected to absorb light at a first wavelength and a concentration of said chromophore component is graded between said bottom surface and said top surface such that said anti-reflective coating exhibits optical properties that transition between said bottom surface and said top surface from absorbing light at a first wavelength to transmitting light at said first wavelength,
wherein said concentration of said chromophore component at said bottom surface is predetermined so that a first refractive index of said first layer at said bottom surface approximately matches a second refractive index of said substrate; and
wherein said concentration of said chromophore component at said top surface is predetermined such that a third refractive index of said second layer at said top surface approximately matches a fourth refractive index of a selected photo-resist material positioned above said second layer.

8. A method of forming an anti-reflective coating, said method comprising:
forming a first layer on a substrate, wherein said first layer is formed with a first polymer component and a chromophore component and wherein said chromophore component is selected so that said first layer absorbs light at first wavelength;
forming a second layer on said first layer, wherein said second layer is formed with second polymer component and transmits light at said first wavelength; and
heating said first layer and said second layer to diffuse a portion of said chromophore component from said first layer into a lower section of said second layer in order to create a graded chromophore concentration between a bottom surface of said anti-reflective coating and a top surface of said anti-reflective coating,
wherein due to said graded chromophore concentration, said anti-reflective coating exhibits optical properties that transition between absorbing light at said first wavelength at said bottom surface and transmitting light at said first wavelength at said top surface.

9. The method claim 8,
wherein said first layer is further formed with a solvent component and
wherein said method further comprises before said forming of said second layer, heating said first layer to remove said solvent component and to partially cross-link said first polymer component such that during said heating of said first layer and said second layer diffusion of said chromophore component into said lower section is limited.

10. The method of claim 8, wherein said forming of said first layer comprises combining said chromophore component with said first polymer component such that said chromophore component is approximately 30-50 mole percent of said first layer.

11. The method of claim 10, wherein said combining comprises one of chemically attaching said chromophore component to a backbone of said first polymer component and blending said chromophore component with said first polymer component.

12. The method of claim 8, wherein said forming of said second layer further comprises forming said second layer with a second chromophore component such that said second chromophore component is approximately 0-20 mole percent of said second layer.

13. The method claim 8, further comprising selecting polymers with glass transition temperatures that are between approximately 80 and 100° C. for said first polymer component and said second polymer component.

14. The method claim 8, further comprising selecting one of acrylate-based polymers and styrene-based polymers for said first polymer component and said second polymer component.

15. The method claim 8, wherein said forming of said first layer comprises forming said first layer to have a first refractive index that is approximately equal to a second refractive index of said substrate and wherein said forming of said second layer comprises forming said second layer to have a third refractive index that is approximately equal to a fourth refractive index of a selected photo-resist material.

16. A method of forming an anti-reflective coating, said method comprising:
forming a first layer on a substrate, wherein said first layer is formed with a first polymer component, a first solvent and a chromophore component and wherein said chromophore component is selected so that said first layer absorbs light at first wavelength;
forming a second layer on said first layer, wherein said second layer is formed with a second polymer component and a second solvent and transmits light at said first wavelength; and
heating said first layer and said second layer to intermix an upper section of said first layer with a lower section of said second layer in order to create a graded chromophore concentration between a bottom surface of said anti-reflective coating and a top surface of said anti-reflective coating,
wherein due to said graded chromophore concentration, said anti-reflective coating exhibits optical properties that transition between absorbing light at said first wavelength at said bottom surface and transmitting light at said first wavelength at said top surface.

17. The method claim 16,
wherein said first layer is further formed with a solvent component,
wherein said method further comprises, before said forming of said second layer, heating said first layer to remove said solvent component and to partially cross-link said first polymer component, and
wherein contact with said second solvent causes swelling of said first layer which enhances intermixing of said upper section of said first layer and said lower section of said second layer.

18. The method of claim 16, wherein said forming of said first layer comprises one of chemically attaching said chromophore component to a backbone of said first polymer component and blending said chromophore component with said first polymer component.

19. The method claim 16, further comprising selecting one of acrylate-based polymers and styrene-based polymers for said first polymer component and said second polymer component.

20. The method claim 16, wherein said forming of said first layer comprises forming said first layer to have a first refractive index that is approximately equal to a second refractive index of said substrate and wherein said forming of said second layer comprises forming said second layer to have a third refractive index that is approximately equal to a fourth refractive index of a selected photo-resist material.
